(19) United States
(12) Patent Application Publication
(10) Pub. No.: US 2026/0289360 A1
(43) Pub. Date: Sep. 24, 2026

(54) FIELD-PROGRAMMABLE ISING MACHINE AND METHOD OF USING

(71) Applicants: The Regents of the University of California, Oakland, CA (US); Yale University, New Haven, CT (US)

(72) Inventors: Jaijeet Shankar ROYCHOWDHURY, Berkeley, CA (US); Rajit MANOHAR, New Haven, CT (US)

(21) Appl. No.: 19/474,212

(22) PCT Filed: Apr. 26, 2024
(86) PCT No.: PCT/US2024/026623

§ 371 Date: Oct. 10, 2025

Related U.S. Application Data
(60) Provisional application No. 63/462,103, filed on Apr. 26, 2023.

(51) Int. Cl. G06N 7/01; G06F 15/78

(52) U.S. Cl. CPC G06N 7/01; G06F 15/7892

(57) ABSTRACT

A programmably reconfigurable Ising machine. In embodiments, the programmably reconfigurable Ising machine includes a plurality of spin circuits and a reconfigurable routing network. Each spin circuit includes a spin generator and a set of reconfigurable coupling blocks operatively connected to the spin generator. In embodiments, each reconfigurable coupling block includes a coupling switch operatively connected to the spin generator, a variable coupling unit operatively connected to the coupling switch, and a pin operably connected to the variable coupling unit. In embodiments, the coupling switch and the variable coupling unit are connected to memory and are configurable based on a configuration stored in the memory. In embodiments, the reconfigurable routing network is configured to selectively operatively connect two or more spin circuit of the programmably reconfigurable Ising machine via reconfigurable coupling blocks. Connected spin circuits are interdependent.

### REFERENCE TO RELATED APPLICATIONS

The present application claims priority to and the benefit of U.S. Provisional Patent Application Ser. No. 63/462,103, filed Apr. 26, 2023, and entitled “FIELD-PROGRAMMABLE ISING MACHINE AND METHOD OF USING,” the entire contents of which are hereby incorporated by reference herein.

### STATEMENT OF GOVERNMENT SUPPORT

The invention was made with government support under Grant Number FA8650-23-C-7311 awarded by the DOD Advanced Research Projects Agency. The government has certain rights in the invention.

### FIELD OF THE INVENTION

The present invention generally relates to Ising machines that are field programmable.

### BACKGROUND OF THE INVENTION

The Boolean Satisfiability (“SAT”) problem is a fundamental, classically difficult NP-complete/hard combinatorial optimization (“CO”) problem [20, 21] with a wide variety of practical applications [22]. A SAT problem is typically expressed in conjunctive normal form (“CNF” [21]), where each conjunct is the OR of a set of variables or inverted variables. This is a logical expression; the problem is to determine if there exists an assignment of truth values (“false” or “true”) to the set of variables or inverted variables where the Boolean expression is satisfied.

The Ising model is a general formulation for CO problems [9], including SAT problems, based on a cost function, called the Ising Hamiltonian, as shown in Eq. 1:

$$H ( {s}_{1} , … , {s}_{n} ) {=}^{△} = - \frac{1}{2} {{\sum }_{i = 1}}^{n} {{\sum }_{j = 1}}^{n} {J}_{ij} {s}_{i} {s}_{j}$$

where H is the Hamiltonian, s₁, . . . , sₙ are spins s₁ through sₙ, each spin with a value of either +1 or −1, Jᵢⱼ is a real-valued weight associated with the connection of couplings between the ith and jth spins (whose values are sᵢ and sⱼ, respectively). The weights are symmetric, such that Jᵢⱼ is equal to Jⱼᵢ. The Ising Hamiltonian above may reflect the “magnetic-field” bias by using an extra spin set to 1. The Ising problem is to find a set of spin assignments that minimizes the Hamiltonian.

In recent years. Ising Machines (“IMs”) have gained traction as a viable approach for solving hard combinatorial optimization (CO) problems. Ising Machines (“IMs”) use specialized hardware, typically based on quantum, probabilistic or analog physics/mathematics, for solving CO problems reformulated in so-called Ising form, by seeking to solve for the Hamiltonian minimum described by Eq. 1. Though Ising Machines were initially inspired by quantum computers [1, 2], a class of analog Ising Machines that operate on purely classical principles has arisen. Such analog Ising Machines are able to solve many standard CO problems competitively vs. quantum Ising Machines, while typically being far simpler, smaller and cheaper. In analog Ising machines, spins are implemented or generated using analog circuits. For example. Oscillator Ising Machines (OIMs) [16] use oscillators whose phases encode spins, Bistable Resitively-Coupled Ising Machines (“BRIMs”) [4, 5] use Zero Inductor-Voltage (“ZIV”) diodes and Bistable Latch Ising Machines (“BLIMs”) [5] uses latches, all in analog operation. Connections between spins, or coupling weights, are typically implemented using resistors.

Analog Ising solvers that can be fabricated on chip, e.g., in standard complementary metal-oxide semiconductor (“CMOS”) technologies examples include OIM [3]. BRIM/BLIM [4, 5] and related approaches [6], represent one potential solution. In analog Ising solvers, circuits such as oscillators or analog latches function as Ising “spins”. Complex analog dynamics engendered by physical connections between the spins underlie their ability to solve CO problems. A very different approach for solving Ising problems is digital emulation, solving mathematical models of analog Ising machines using fixed- or floating-point numerical methods implemented as custom ICs or on conventional Field-Programmable Gate Arrays (“FPGAs”) (e.g., [7, 8]). The potential benefits of such on-chip analog Ising Machines over quantum and/or optical ones include reductions in physical size, energy consumption and cost of many orders of magnitude, as well as feasible scaling to large problem sizes.

However, delivering the above-noted promise for practical CO problems requires careful consideration of the scalability of problem mapping to Ising form and the sparsity of connectivity (the average number of spins each spin is connected to), which may be ‘dense’ (e.g., where each spin is coupled to every other spin) or ‘sparse’ (e.g., where each spin, on average, is coupled to only a few other spins). For example, the number of Ising spins needed for the Travelling Salesman Problem (TSP) grows quadratically with respect to problem size [9]. Mapping the Multiple-user, Multiple-Input and Multiple-Output (“MU-MIMO”) detection problem does not lead to more spins [10, 11], but all-to-all connectivity is required, presenting an on-chip implementation challenge [12].

Typically, to implement an Ising machine on chip at scale, the number of spins in the Ising form of a CO problem should scale only modestly with problem size. Three further metrics may be important: the number of spins needed, the connection sparsity and the Bits of Coupling Resolution (“BCR”) required to implement the weights. The number of spins corresponds to the number of hardware modules needed on a chip. Sparsity refers to the average number of spins each spin is coupled to. If a problem's Ising formulation is sparse, on-chip hardware implementation may be simpler than if, e.g., the coupling is dense. This is due to the difficulty of routing dense connections. For example, where each spin is connected to every other spin, the number of wires (or traces) may be represented by (½)(n)(n−1), where n is the number of spins. If n=1000 spins, the number of couple interconnections is 499,500. However, where the problem is sparse, with average node degree d<<n−1, then the total number of coupling interconnections needed is n(d/2), which may be routed more easily. In almost all existing ICs, d is typically a small constant, much lower than the number of units that need to be connected; for example, d for a digital CMOS chip is typically between three and four. Bits of Coupling Resolution (“BCR”) refers to the number of bits needed to program the coupling resistors in analog Ims. A Bits of Coupling Resolution of b bits supports 2^{b} different settable coupling values. The required BCR depends on the nature of the Ising problem to be solved. The complexity of the circuit implementation of each programmable coupling (resistor) depends directly on the BCR, since a switched ladder network, requiring b switching elements, is typically employed.

Typically, Sparsity and Bits of Coupling Resolution both depend on the problem to be solved and its Ising mapping. Conventionally, for easy IC implementation, a problem would ideally be sparse and also feature low Bits of Coupling Resolution.

Another key issue for on-chip realization is configuring different connectivity patterns to address different problems. Previous work has relied on re-mapping the Ising problem onto a larger Ising fabric with a fixed sparse connection topology, such as Chimera, Pegasus or King's graphs [13, 6, 14]. Re-mapping typically increases Ising problem size greatly [15], severely limiting the sizes of CO problems that can be solved with a fixed number of spins on an IC.

What is needed is a way to solve complex problems featuring different sparse coupling connectivity configurations on the same chip while reducing chip size compared to the conventional methods.

### SUMMARY OF THE INVENTION

In view of the above, it is an object of the present disclosure to provide a programmably reconfigurable Ising machine including: (a) a plurality of spin circuits, including a first spin circuit and a second spin circuit, and (b) a reconfigurable routing network configured to selectively operatively connect the first spin circuit to at least the second spin circuit based on computer instructions. In embodiments, each of the plurality of spin circuits includes: (i) a spin generator; (ii) a set of reconfigurable coupling blocks operatively connected to the spin generator. In embodiments, each of the reconfigurable coupling blocks includes a coupling switch operatively connected to the spin generator, a variable coupling unit operatively connected to the coupling switch; and a pin operatively connected to the variable coupling unit.

In embodiments, a first spin generator of the first spin circuit and a second spin generator of the second spin circuit are interdependent when the first spin generator and the second spin generator are operatively connected and independent when the first spin generator and the second spin generator are not operatively connected.

In embodiments, the spin generator includes an oscillator.

In embodiments, the spin generator includes a latch.

In embodiments, at least one of the plurality of spin circuits includes at least two spin generators.

In embodiments, the programmably reconfigurable Ising machine includes memory operatively connected to the coupling switch and the variable coupling unit, wherein the coupling switch is configured to obtain a respective switch configuration stored in the memory, and wherein of the variable coupling unit is configured to obtain a respective coupling configuration stored in the memory. In embodiments, the memory is static random access memory. In embodiments, the memory is flash memory.

In embodiments, at least one of the plurality of spin circuits further includes iii) a wire operatively connected to the spin generator and a pin and configured to carry an analog signal. In embodiments, the analog signal is configured to set a spin of a spin generator of at least one of the plurality of spin circuits to a predetermined value. In embodiments, the analog signal is configured to set a first spin of the first spin circuit to a value of a second spin of the second spin circuit.

In view of the above, it is an object of the present disclosure to provide a programmably reconfigurable Ising machine including: (a) a plurality of spin circuits, including a first spin circuit and a second spin circuit and (b) a reconfigurable routing network configured to selectively operatively connect the first spin circuit to at least the second spin circuit based on computer instructions. In embodiments, each of the plurality of spin circuits includes: (i) a spin generator; and (ii) a set of reconfigurable coupling blocks operatively connected to the spin generator. In embodiments, a first spin generator of the first spin circuit and a second spin generator of the second spin circuit are interdependent when the first spin generator and the second spin generator are operatively connected and independent when the first spin generator and the second spin generator are not operatively connected.

In embodiments, the first spin circuit and the second spin circuit are connected via at least one connection block.

In embodiments, the first spin circuit and the second spin circuit are connected via at least two connection blocks and a switch block.

In embodiments, the plurality of spin circuits includes a third spin circuit. In embodiments, the reconfigurable routing network is further configured to selectively operatively connect the third spin circuit to the first spin circuit, the third spin circuit to the second spin circuit, and the third spin circuit to the first and second spin circuit.

In embodiments, the plurality of spin circuits includes at least 250 spin circuits.

In embodiments, the plurality of spin circuits includes at least 500 spin circuits.

In embodiments, the plurality of spin circuits includes at least 1,000 spin circuits.

In embodiments, the plurality of spin circuits includes at least 2.000 spin circuits.

In embodiments, the plurality of spin circuits includes at least 10,000 spin circuits.

In view of the above, it is a further object of the present disclosure to provide a programmably reconfigurable Ising machine, the programmably reconfigurable Ising machine including (a) a plurality of spin circuits, wherein each of the plurality of spin circuits includes: (i) a spin generator; (ii) a set of reconfigurable resistor blocks operatively connected to the spin generator, wherein each of the reconfigurable resistor blocks includes: (1) a coupling switch operatively connected to the spin generator: (2) a variable resistor operatively connected to the coupling switch; and (3) a set of state bits, wherein the set of state bits is operatively connected to the coupling switch and the variable resistor, and wherein the set of state bits is configurable to set a respective state of the coupling switch and a respective state of the variable resistor depending on the value of the set of respective state bits; and (iii) a bidirectional port operatively connected to the set of reconfigurable resistor blocks; and (b) a reconfigurable routing network configurable to operatively connect respective spin circuits via the respective bidirectional ports of the respective spin circuits of the plurality of spin circuits.

In embodiments, the spin generator includes an oscillator and/or a latch.

In embodiments, the set of state bits are stored in static random access memory and/or in flash memory.

In embodiments, the at least one of the plurality of spin circuits includes at least two spin generators.

In embodiments, the spin circuit further includes (iv) a wire operationally connected to the spin generator and the bidirectional port and configured to carry an analog signal. In embodiments, the analog signal may be configured to set a spin of the spin generator to a predetermined value and/or to a value of a second spin.

In embodiments, the reconfigurable routing network includes (i) a plurality of connection blocks, wherein each of the plurality of connection blocks includes a set of spin circuit connection wire segments and a set of channel wire segments, wherein each spin circuit connection wire segment of the set of spin circuit connection wire segments is configurable to connect to the bidirectional port of a respective spin circuit to the set, and wherein the set of channel wire segments are operably connected to the spin circuit connections wire segment; and (ii) a plurality of reconfigurable switch blocks, wherein each reconfigurable switch block of the plurality of reconfigurable switch blocks includes a programmable routing switch operationally connected to at least two respective sets of channel wire segments, the programmable routing switch programmable to operationally connect the at least two respective sets of channel wire segments.

In embodiments, the plurality of spin circuits includes at least 250 spin circuits, at least 500 spin circuits, at least 1,000 spin circuits, at least 2,000 spin circuits, and/or at least 10,000 spin circuits.

In view of the above, it is a further object of the present disclosure to provide a programmably reconfigurable Ising machine including: (a) a first spin circuit, wherein the first spin circuit includes (i) a first spin generator: (ii) a first set of reconfigurable resistor blocks operatively connected to the first spin generator, wherein each of the first set of reconfigurable resistor blocks includes (1) a first coupling switch operatively connected to the first spin generator; (2) a first variable resistor operatively connected to the first coupling switch; and (3) a first set of state bits, wherein the first set of state bits is operatively connected to the first coupling switch and the first variable resistor, wherein the first set of state bits is configurable to set a first respective switch state of the first coupling switch and a first respective resistance state of the first variable resistor depending on the value of the first set of respective state bits; and (iii) a first bidirectional port operatively connected to the first set of reconfigurable resistor blocks; (b) a second spin circuit, wherein the second spin circuit includes: (i) a second spin generator; (ii) a second set of reconfigurable resistor blocks operatively connected to the second spin generator, wherein each of the second set of reconfigurable resistor blocks includes: (1) a second coupling switch operatively connected to the second spin generator; (2) a second variable resistor operatively connected to the second coupling switch; and (3) a second set of state bits, wherein the second set of state bits is operatively connected to the second coupling switch and the second variable resistor, wherein the second set of state bits is configurable to set a second respective switch state of the second coupling switch and a second respective resistance state of the second variable resistor depending on the value of the second set of respective state bits; and (iii) a second bidirectional port operatively connected to the second set of reconfigurable resistor blocks; (c) a reconfigurable routing network configurable to operatively connect the first spin circuit and the second spin circuit via the first bidirectional port and the second bidirectional port.

In embodiments, the first spin generator and the second spin generator include an oscillator and/or a latch.

In embodiments, the first set of state bits and the second set of state bits are stored in static random access memory and/or in flash memory.

In embodiments, the first spin circuit further includes (iv) a wire operationally connected to the first spin generator and the first bidirectional port and configured to carry a first analog signal. In embodiments, the first analog signal may be configured to set a first spin of the first spin generator to a predetermined value and/or to a value of a second spin.

In embodiments, the second spin circuit further includes (iv) a wire operationally connected to the second spin generator and the second bidirectional port and configured to carry a second analog signal. In embodiments, the second analog signal may be configured to set a second spin of the second spin generator to a predetermined value and/or to a value of a third spin. In embodiments, the third spin may be the first spin of the first spin generator.

In embodiments, the reconfigurable routing network includes (i) a first connection block, wherein the first connection block includes a first set of spin circuit connection wire segments and a first set of channel wire segments, wherein the first set of spin circuit connection wire segments is connected to the first bidirectional port and wherein the first set of channel wire segments are connected to the first set of spin circuit connection wire segments; (ii) a second connection block, wherein the second connection block includes a second set of spin circuit connection wire segments and a second set of channel wire segments, wherein the second set of spin circuit connection wire segments is connected to the second bidirectional port and wherein the second set of channel wire segments are connected to the second set of spin circuit connection wire segments; and (iii) a first reconfigurable switch block, wherein the first reconfigurable switch block includes a first programmable routing switch, the first programmable routing switch programmable to operationally connect at least one of the first set of channel wire segments and at least one of the second set of channel wire segments

In embodiments, the programmably reconfigurable Ising machine further includes (d) a third spin circuit, wherein the third spin circuit includes (i) a third spin generator; (ii) a third set of reconfigurable resistor blocks operatively connected to the third spin generator, wherein each of the third set of reconfigurable resistor blocks includes (1) a third coupling switch operatively connected to the third spin generator; (2) a third variable resistor operatively connected to the third coupling switch; and (3) a third set of state bits, wherein the third set of state bits is operatively connected to the third coupling switch and the third variable resistor, wherein the third set of state bits is configurable to set a third respective switch state of the third coupling switch and a third respective resistance state of the third variable resistor depending on the value of the third set of respective state bits; and (iii) a third bidirectional port operatively connected to the third set of reconfigurable resistor blocks; and wherein the reconfigurable routing network is further configurable to operatively connect the first spin circuit and the third spin circuit via the first bidirectional port and the third bidirectional port and is further configurable to operatively connect the second spin circuit and the third spin circuit via the second the second bidirectional port and the third bidirectional port.

In embodiments, the reconfigurable routing network further includes (iv) a third connection block, wherein the third connection block includes a third set of spin circuit connection wire segments and a third set of channel wire segments, wherein the third set of spin circuit connection wire segments is connected to the third bidirectional port and wherein the third set of channel wire segments are connected to the third set of spin circuit connection wire segments.

In embodiments, the first programmable routing switch is further programmable to operationally connect at least one of the first set of channel wire segments and at least one of the third set of channel wire segments and to operationally connect at least one of the second set of channel wire segments and at least one of the third set of channel wire segments.

In embodiments, reconfigurable routing network includes (v) a second reconfigurable switch block, wherein the second reconfigurable switch block includes a second programmable routing switch, the second programmable routing switch programmable to operationally connect at least one of the second set of channel wire segments and at least one of the third set of channel wire segments.

In embodiments, the first programmable routing switch is further programmable to operationally connect at least one of the first set of channel wire segments and at least one of the third set of channel wire segments.

In embodiments, the programmably reconfigurable Ising machine includes at least 250 spin circuits, at least 500 spin circuits, at least 1,000 spin circuits, at least 2,000 spin circuits and/or at least 10,000 spin circuits.

### BRIEF DESCRIPTION OF THE DRAWINGS

The above and related objects, features and advantages of the present disclosure will be more fully understood by reference to the following detailed description of the preferred, albeit illustrative, embodiments of the present invention when taken in conjunction with the accompany figures, wherein:

FIG. 1 provides a depiction of a generated Ising equivalent network which represents the equivalent of an OR gate used in accordance with embodiments of the present invention;

FIG. 2A depicts a gate-level circuit with two digital OR gates chained together used in accordance with embodiments of the present invention;

FIG. 2B depicts an Ising equivalent network of the gate-level circuit in FIG. 2A, with an output spin set to +1 in accordance with embodiments of the present invention;

FIG. 3 depicts a logic diagram of an exemplary island-style Field Programmable Ising Machine architecture in accordance with embodiments of the present invention;

FIG. 4 shows an example SAT problem placed and routed on a Field Programmable Ising Machine in accordance with embodiments of the present invention; and

FIG. 5 is a histogram of routing track requirements for an example where mirrored spins are used in accordance with embodiments of the present invention.

### DETAILED DESCRIPTION OF THE INVENTION

The present disclosure generally relates to a programmably reconfigurable Ising machine.

In embodiments, the programmably reconfigurable Ising machine includes (a) a plurality of spin circuits, including a first spin circuit and a second spin circuit and (b) a reconfigurable routing network configured to selectively operatively connect the first spin circuit to at least the second spin circuit based on computer instructions. In embodiments, each of the plurality of spin circuits includes: (i) a spin generator; and (ii) a set of reconfigurable coupling blocks operatively connected to the spin generator. In embodiments, a first spin generator of the first spin circuit and a second spin generator of the second spin circuit are interdependent when the first spin generator and the second spin generator are operatively connected and independent when the first spin generator and the second spin generator are not operatively connected.

In embodiments, the programmably reconfigurable Ising machine includes a plurality of spin circuits and a reconfigurable routing network. In embodiments, each spin circuit includes a spin generator, a set of reconfigurable resistor blocks operatively connected to the spin generator, and a bidirectional port operatively connected to the set of reconfigurable resistor blocks. In embodiments, each set of reconfigurable resistor blocks includes a coupling switch operatively connected to the spin generator, a variable resistor operatively connected to the coupling switch, and a set of state bits. In embodiments, the set of state bits are operatively connected to the coupling switch and the variable resistor, and are configurable to set a respective state of the coupling switch and a respective state of the variable resistor depending on the value of the set of respective state bits. In embodiments, the reconfigurable routing network is configurable to operatively connect respective spin circuits.

Embodiments of the present disclosure provide Ising machines that are field programmable

### A. Overview

The present disclosure details how to design an analog Ising chip that can solve problems featuring different (sparse) coupling connectivities on the same chip. Prior chip-based approaches towards this goal focused on mapping problems onto a fixed connectivity topology such as Chimera and Pegasus [13] and King's graphs [15, 6]. Embodiments of the present disclosure provide a much more general scheme involving programmable connectivity fabrics, providing advantages over conventional Ising machines. Furthermore, while the embodiments described herein relate to SAT problems, it will be understood that that they may be used for other problem classes as well.

To realize the potential benefits of analog Ising solvers, a CO problem class must have an Ising mapping that does not explode with problem size and also satisfies other constraints tied to realistic on-chip implementation. The present disclosure provides a solution to the challenges facing the field of art, specifically by detailing how SAT problems can be mapped to a practical reconfigurable Ising solver architecture, dubbed a field programmable Ising machine (“FPIM”). In embodiments, field programmable Ising machines are not necessarily tied to a specific analog Ising scheme; field programmable Ising machine's may use spins based on, e.g., oscillators [16]. ZIV diodes [4]. CMOS latches [5], etc. While embodiments of field programmable Ising machines are similar in some aspects to an FPGAs, there are key differences between the two. In embodiments of the present invention, in field programmable Ising machines, analog spin circuits, as opposed to digital Look-Up Tables used in Field Programmable Gate Arrays, are coupled bi-directionally (e.g., allowing signals to transfer between two connected spin circuits) using programmable resistive connections that implement Ising weights. Analog operation enables a field programmable Ising machine to solve a CO problem using mechanisms completely different from the digital computations that FPGAs accelerate.

Embodiments of the present disclosure provide a novel, effective way to design and/or synthesize practical field programmable Ising machines for SAT problems. In exemplary embodiments, logic synthesis tools may be employed (yosys [17], ABC [18]) as a first step to obtain gate-level circuits for SAT functions to be solved. In embodiments, a SAT problem given in CNF (or any other form) may be synthesized as a standard gate level circuit implementation whose output is logic 1 (true) if, and only if, the problem is satisfiable. Second, a SAT-to-Ising mapping procedure may be used to replace each logic gate with an “Ising equivalent” (with a known minimum-Hamiltonian state, or known ground state) of a corresponding Ising problem. In embodiments, the Ising equivalent (also referred to herein as an Ising equivalent network) consists of a few spin units with weighted couplings. In embodiments, Ising equivalents are defined at the Ising graph level and implemented using any circuit level analog spin scheme. Analog dynamics enables the Ising network to settle to a SAT solution when the output spin is set to +1. Third, in embodiments, an FPGA-like Ising solver chip is devised that connects gates' Ising equivalents reconfigurably.

This method presents several advantages. In embodiments, sparse connectivity between logic gates translates to sparse connectivity in the Ising equivalent network. Since widely available logic synthesis tools (e.g., yosys. ABC [17, 18]) are very good at synthesizing sparsely connected, practically routable gate-level circuit implementations of virtually any multi-input logic function, the embodiments of the present disclosure are able to map SAT problems into sparse, routable Ising solver ICs. Moreover, the Bits of Coupling Resolution needed for the Ising network is proportional to the maximum number of connections to/from any single gate (maximum fan-in +fan-out) in this scheme. An advantage of the present disclosure is that since any combinational logic gate/function can be broken down into connections/compositions of e.g., two-input, one-output gates, in most embodiments, the typical Bits of Coupling Resolution does not increase with the size of the SAT problem. These features of the above-described field programmable Ising machine flow are well suited for practical on-chip implementation at scale.

In virtual experiments, field programmable Ising machine demonstrate that they can be scaled easily from small to large SAT problem size. Size/area and the routing architecture of a field programmable Ising machine may depend principally on three metrics: 1) the number of spins, 2) the number of couplings per spin (sparsity), and 3) the number of bits of coupling resolution needed. These metrics depend not only on the specific SAT problem, but also on choices that can be exercised during SAT-to-Ising mapping. In experiments, the number of spins needed grows almost linearly as O(n1.1) as SAT problem sizes increase. Moreover, sparsity and BCR stay at small values that do not grow with the SAT problem's size. In embodiments, after running place and route, all 1000 uf20 problems of DIMACS SATLIB [19] can be mapped to an field programmable Ising machine with fewer than 6 tracks, and 9 tracks suffice for the 1000 uf50 problems of DIMACS SATLIB.

### B. FPIMs: Field-Programmable Ising Machines

### I. A SAT to Ising Mapping for Flexible On-Chip Implementation

In embodiments, the first step in the SAT-to-Ising flow is to map a given logical expression for SAT to a gate-level circuit using logic synthesis tools. Given a user-specified gate library, such tools can realize a Boolean expression as a logic network using gates from the library. Different problems will, in general, map to gate-level networks with different connectivity and primitive gates from the specified library. Simply realizing a problem's Boolean function as a logic gate-level network does not help solve it for SAT, however.

An advantage of the present disclosure is that it enables the solving of SAT and other complex problems which the generated logic gate-level network cannot, by converting the network to an Ising machine capable of solving the SAT problem, even though the connection of logic gates it is based on cannot. In embodiments, to generate an IM, each logic gate is mapped to a small Ising equivalent network, in which the inputs and output of output of the logic gate are represented by Ising spins.

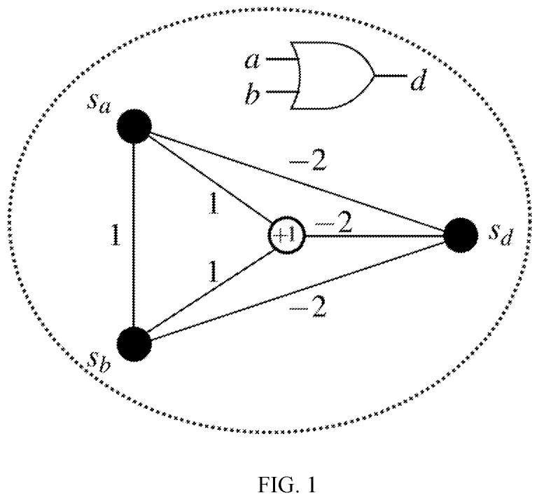

FIG. 1 provides a depiction of a generated Ising equivalent network which represents the equivalent of an OR gate used in accordance with embodiments of the present invention. As depicted in FIG. 1, the Ising equivalent network may include a plurality of spins, such as spins sa, sb, a center spin, and sd. In embodiments, spins sa and sb may be inputs and spin sd may be an output. In embodiments, the center spin may be fixed at a value. In embodiments the value may be +1 or −1. In embodiments, there may be one or more coupling weights assigned to the couplings between the spins. For example, as depicted in FIG. 1, to generate the Ising equivalent network of an OR gate, coupling cab between sa and sb, coupling ca between the center spin and sa, as well as coupling cb between the center spin and sb may have a weighting of 1, and couplings cd, cda, and cdb between the spins sd and the center spin, sa and sb, respectively, may have a weighting of −2.

In embodiments, the coupling weights are selected such that the Ising equivalent network is capable of performing a typical logical operation. Exemplary weighting are depicted in Table 1:

TABLE 1
Ising 2inp Technology Map

| logic | c_{z} | c_{za} | c_{zb} | cₐ | c_{b} | c_{ab} | H_{SAT} |
|---|---|---|---|---|---|---|---|
| z = false | 1 | 0 | 0 | 0 | 0 | 0 | −1 |
| z = ¬a∧¬b | 2 | 2 | 2 | 1 | 1 | 1 | −3 |
| z = a∨b | −2 | −2 | −2 | 1 | 1 | 1 | −3 |
| z = a∧¬b | 2 | −2 | 2 | −1 | 1 | −1 | −3 |
| z = ¬a | 0 | 1 | 0 | 0 | 0 | 0 | −1 |
| z = ¬a∨¬b | −2 | 2 | 2 | −1 | −1 | 1 | −3 |
| z = a∧b | 2 | −2 | −2 | −1 | −1 | 1 | −3 |
| z = ¬b∨¬∧b | −2 | −2 | 2 | 1 | −1 | −1 | −3 |
| z = a | 0 | −1 | 0 | 0 | 0 | 0 | −1 |

where z represents a logical output, ∅ represents NOT, A represents AND, and V represents OR, cz, cza, czb, ca, cb, cab represent couplings between a center spin and an output spin, the output spin and spin sa, the output spin and spin sb, the center spin and spin sa, the center spin and spin sb, and spin sa and spin sb, respectively, and HSAT represents the minimum Ising Hamilton of the network.

In embodiments, the coupling weights are selected such that if the gate's I/O spins satisfy the Boolean relationship of the desired type of gate, then the Ising Hamiltonian of the Ising equivalent network is the minimum possible, it is the global minimum. In these embodiments, the converse is also true, if spin assignments are not compatible with the logic function of the gate, then the Ising equivalent's Hamiltonian value is strictly greater than its minimum. In embodiments with arbitrary connections of Ising equivalent gates, this remains true. In such embodiments, the minimum possible Hamiltonian is reached if, and only if, the logical relationships of all the connected gates are satisfied.

In embodiments, the Ising version of the synthesized gate-level circuit are enabled to implement a SAT solver by setting its output spin to 1 in hardware, enforcing the SAT condition. In embodiments, fixing the output node to spin 1 constrains the network's minimum Hamiltonian solutions to correspond automatically to SAT solutions and the system's analog dynamics settle naturally to minimum-Hamiltonian solutions. An advantage of the present disclosure over gate-level digital circuits is that no similar solution mechanism is available in gate-level digital circuits, because it implements a directional signal flow graph. For example, referring back to FIG. 1, setting the output spin sd will lead to spins sa and sb into states consistent with the Hamilton minimum. In a conventional digital circuit, setting an output would not lead to changes to the input states, and does not make conceptual sense.

In embodiments, the general expression for the Hamiltonian of an Ising graph equivalent of 1- and 2-input gate with up to 3 spins may be represented by Eq. 2:

$$H = czz + czaza + czbzb + caa + cbb + cabab \qquad ( Eq . 2 )$$

where H is the Hamiltonian, a and b map to the value of the inputs, z to value of the output, and cz, cza, czb, ca, cb, and cab are respective coupling coefficients corresponding to the couplings between the spins of the Ising graph equivalent of the gates. In embodiments, the respective coupling coefficients may be selected such that 2 is minimized if, and only if a truth table defining the logic gate is satisfied. Exemplary coefficients, used in a gate library 2inp, generated in accordance with Table 1 and Eq. 2, are depicted in Table 1. In embodiments, the gate library 2inp may include logic functions AND and OR as well as 1-input NOT and through buffer functions. In embodiments, the gate library 2inp may include other logic functions, for example XOR, NOR and NAND, to name a few. In embodiments, gate logic of the Ising equivalent networks may be verified by calculating the Hamiltonian, using Eq. 2, for each entry in the truth table defining the gate, and ensuring that the network selected results in the Hamiltonian minimum if, and only if the expected logic is satisfied.

In embodiments, Ising equivalent networks are configured so as to solve SAT problems.

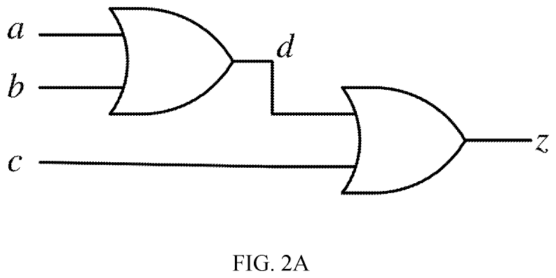

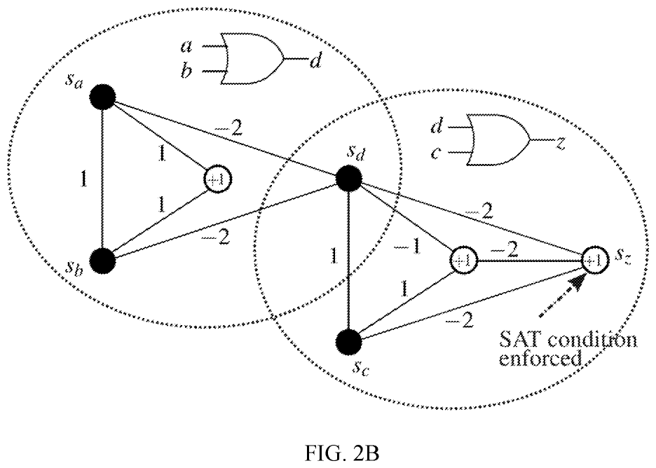

FIG. 2A depicts a gate-level circuit with two digital OR gates chained together used in accordance with embodiments of the present invention. As depicted in FIG. 2A, the OR gates implement Conjunctive Formal Function (“CNF”) clause z=a +b+c=1, where a, b, and c are Boolean inputs and z is a Boolean output. A first OR gate implements d=a +b, and a second OR gate implements the logical equation z=c+d.

FIG. 2B depicts an Ising equivalent network of the gate-level circuit in FIG. 2A, with an output spin set to +1 in accordance with embodiments of the present invention. In embodiments, the Ising equivalent network may be configured to solve an SAT problem in 3 variables a, b, and c with only one CNF clause z=a +b+c=1. In embodiments, the CNF clause may correspond to the Ising equivalent network of FIG. 2B. In embodiments, as depicted in FIG. 2B, the Ising equivalent network may include two connected Ising equivalent networks. In embodiments, a first Ising equivalent network may be similar to the Ising equivalent network depicted by FIG. 1. In embodiments, a second Ising equivalent network may include inputs spin sd and spin sc, where input spin sd corresponds to intermediary output spin sd, a second center spin, and an output spin sz. In embodiments, the second Ising equivalent network may have couplings and coupling coefficients similar to the couplings and coupling coefficients of the Ising equivalent network depicted by FIG. 1. In embodiments, the second Ising equivalent network may have coupling connecting each spin of the second Ising equivalent network to each other spin of the second Ising equivalent network. In embodiments, edges between spin pairs may be merged (e.g., between coupling sd and the first and second center spins). In embodiments, coupling cdc between sd and sc, as well as coupling cc between the center spin and sc may have a weighting of 1, coupling cd between the center spin and sd may have a weighting of −1 (representing the summed weight of −2 of the first Ising equivalent network and +1 of the second Ising equivalent network) and couplings cz, czd, and czc between the spins sz and the center spin, sd and sc, respectively, may have a weighting of −2. In embodiments, the value of the second center spin may be set to +1. In embodiments, the second center spin may be the same spin as the first center spin.

In embodiments, as illustrated by FIGS. 2A and 2B, an arbitrary number of Ising equivalent networks may be chained together to create a logic gate. For example, a different SAT problem may be solved using a different configuration of Ising equivalent networks and/or a greater or fewer number of Ising equivalent networks.

### II. Reconfigurable Networks of Gate Ising-Equivalents: Field Programmable Ising Machines

In embodiments, field programmable Ising machines implement Ising equivalent networks reconfigurably, using techniques similar to those used in Field-Programmable Gate Arrays (“FPGAs”). In embodiments, instead of Look-Up Tables (“LUTs”) as primitive building blocks (as in FPGAs), field programmable Ising machines use hardware spin representations (e.g., oscillators for Oscillator Ising Machine, ZIV diodes for Bistable Resitively-Coupled Ising Machines, CMOS latches for Bistable Latch Ising Machines, to name a few) as basic elements. In embodiments, field programmable Ising machines include programmable interconnect, which may include a routing network. In embodiments, field programmable Ising machines include programmable weights. In embodiments, the bits of coupling resolution supported by the field programmable Ising machine architecture may be related to the suitability of an Ising machine for a given set of SAT or other problems. In embodiments, field programmable Ising machines may use an island-style architecture, including Ising clusters consisting of a small array of spins, each with programmable resistance values between them in a dense sub-array. In embodiments where a field programmable Ising machine is configured to solve SAT problems, average node connectivity d may be quite small, as global connectivity between spins may be sparse.

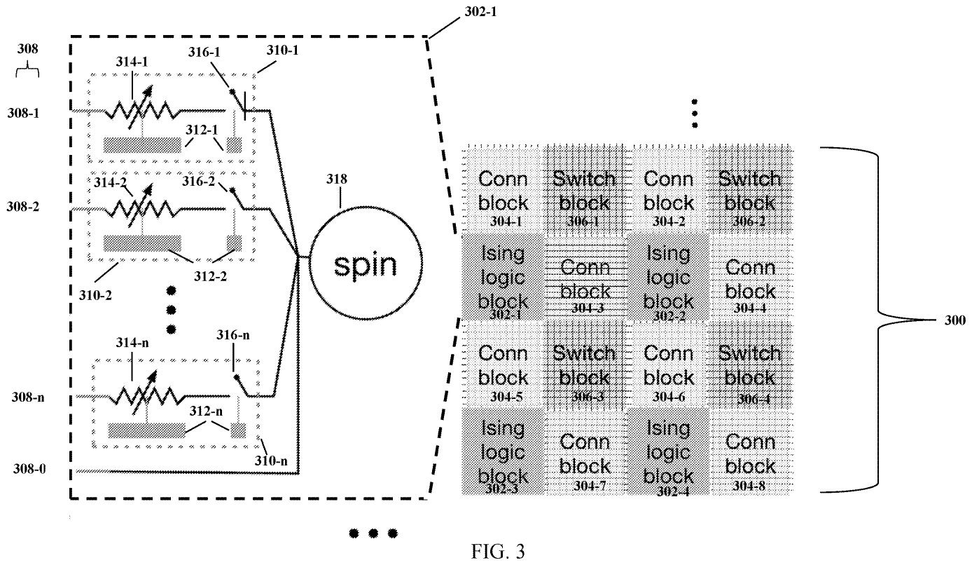

FIG. 3 depicts a logic diagram of an exemplary island-style field programmable Ising machine architecture in accordance with embodiments of the present invention. FIG. 3 depicts a segment 300 of an FPIM consisting of Ising logic blocks 302-1, 302-2, 302-3, 302-4 connected by connection blocks, which may include connection blocks 304-1, 304-2, 304-3, 304-4, 304-5, 304-6, 304-7, 304-8, which are connected by switch blocks 306-1, 306-2, 306-3, 306-4. In embodiments, the FPIM is field programmable; for example, it is a programmably reconfigurable Ising machine. In physical embodiments, wires and/or traces are partially routed over the Ising logic blocks. In embodiments, the connection blocks and switch blocks form a programmable interconnect (also referred to herein as a routing network) and include programmable cross-points to enable and/or disable connections. In embodiments, the programmable cross points are implemented with large pass transistors, an advantage of which is reducing resistance of the programmable interconnect relative to the explicit coupling resistors required. In embodiments, the switch blocks include programmable connectivity between horizontal and vertical routing tracks. In embodiments, connection blocks provide connectivity between the Ising logic block and the interconnect tracks. In embodiments, switches include pass-transistors, an advantage of which is negligible additive resistance values relative to the desired coupling values. In embodiments, point-to-point pipelined interconnect may be similar to that used in high-throughput asynchronous FPGAs [23].

For example, in embodiments, the reconfigurable routing network which is operable to selectively connect the plurality of spin circuits including the first spin circuit and the second circuit includes a first connection block, as second block, and a connection fabric. In embodiments, the first connection block is operatively connected to pins of the first spin circuit and is configured to provide inputs and obtain outputs from the pins of the first spin circuit. Similarly, in embodiments, the second connection block is operatively connected to pins of the second spin circuit and is configured to provide inputs and obtain outputs from the pins of the second spin circuit. In embodiments, the connection fabric is operatively connected to the first connection block and the second block.

Continuing the example, in embodiments, the connection fabric includes routed wires or traces (which can include horizontal and vertical channels of the FPIM) and programmable switches/switch boxes between various wires or traces. In embodiments, the connection blocks and switch blocks are programmable to allow for the coupling of a spin in the first spin circuit with a spin in the second spin circuit by operatively connecting respective pins of both circuits. In embodiments, the connection fabric, allows for Ising logic blocks/spin circuits therein to be selectively connected or disconnected with one another, allowing for reconfigurable coupling by programming the state of, inter alia, the state of the connection boxes and switch boxes.

Still referring to FIG. 3, in embodiments, as depicted in FIG. 3, each Ising logic block (also referred to herein as a “spin circuit”) includes a single spin/spin generator 318. An (Ising) spin is a circuit that can hold two (or more) stable states.

For example, a latch or flip-flop can be used as a spin, or an oscillator (e.g., an oscillator under sub-harmonic injection locking excited by an external signal at roughly twice the natural frequency of the oscillator, to give an example). Generator, as used herein, simply refers to a device or circuit which meets this parameter.

In embodiments, each Ising logic block includes a number of spins. In embodiments, the number of spins is one. In embodiments, the number of spins is at least two. In embodiments, at least one Ising logic block includes a plurality of spins. In embodiments, the spin generators are oscillators (e.g., ring oscillators, negative-resistance LC oscillators, or resistance oscillators, to name a few). The value of the spin may be the value of the oscillator at one or more points in the oscillation. In embodiments, the spin generator is a latch. In embodiments, the spin generator is a ZIV diode. In embodiments, each spin has a value of +1 or −1. In embodiments, the value of a spin depends on/is measured by the physical state of a respective spin generators (e.g., the phase and/or amplitude of an oscillator, to give an example).

In embodiments, each Ising logic block is configured to receive signals 308 (for example, consisting of signals 308-0, 308-1, 308-2 . . . 308-n) and includes reconfigurable hardware 310 (for example, consisting of reconfigurable hardware 310-1, 310-2 to 310-n). In embodiments, each of the signals 308 may be propagated via wiring from a port or pin (not shown) of the Ising logic block. In embodiments, the pin is bidirectional. In embodiments, the Ising logic block is configured to receive and send signals using separate channels. In embodiments, each pin is unidirectional.

In embodiments, as shown in FIG. 3, the programmably reconfigurable Ising machine includes a plurality of spin circuits (e.g., Ising logic blocks 302-1, 302-2, 302-3, 302-4), including a first spin circuit (e.g., Ising logic block 302-1) and a second spin circuit (e.g., Ising logic block 302-2). In embodiments, each spin circuit includes a spin generator (e.g., spin generator 318/measurement thereof) and a set of reconfigurable coupling blocks (e.g., the reconfigurable hardware 310-1, 310-2, 310-3 . . . 310-n, to give an example).

In embodiments, each of the sets of reconfigurable coupling blocks (the reconfigurable hardware) includes a coupling switch operatively connected to the spin generator (e.g., coupling switch 316-1, 316-2, and 316-n, to give examples), a variable coupling unit operatively connected to the programing switch, (e.g., programmable resistors 314-1, 314-2 and 314-n, to give examples), and a pin operatively connected to the variable coupling unit. For example, as shown in FIG. 3, reconfigurable coupling block 310-1 includes programmable resistor 314-1 and coupling switch 316-1, reconfigurable couple block 310-2 includes programmable resistor 314-2 and coupling switch 316-2, and reconfigurable coupling block 310-n includes programmable resistor 314-n and coupling switch 316-n.

In embodiments, spin circuits are coupled using other forms of reconfigurable coupling blocks and variable coupling unit. For example, in embodiments, as described by U.S. Provisional Application Ser. No. 63/639,281, filed on Apr. 26, 2024, active one-way resistor coupling is used. As an example, in such embodiments, a first reconfigurable coupling block includes a variable coupling unit including a first one-way buffered gm coupling unit, which is configurable to couple a first spin circuit to a second spin circuit, and a second reconfigurable coupling block includes a second variable coupling unit including a second one-way buffered gm coupling unit, which is configurable to couple the second spin circuit to the first spin circuit. In embodiments, the first and second reconfigurable coupling blocks further include switches and/or other routing hardware used to selectively connect and disconnect the coupling hardware with one or more spin circuits. In embodiments, the first and second reconfigurable coupling blocks include a pin.

As another example, in embodiments, as disclosed by U.S. Provisional Application Ser. No. 63/639,281, filed on Apr. 26, 2024, multiplicative coupling/sampling coupling is used. As an example, in such embodiments, a first reconfigurable coupling block for use with a programmably reconfigurable Ising machine includes a first coupling unit which includes a first sampling circuit (e.g., a first flip-flop) and a first current source operatively connected to the first sampling circuit, which is operable to couple a first spin circuit with a second spin circuit by sampling the second spin circuit at one or more transitions of the first spin circuit. Continuing the example, in embodiments, a second reconfigurable coupling block for use with the programmably reconfigurable Ising machine includes a second coupling unit which includes a second sampling circuit (e.g., a first flip-flop) and a first current source operatively connected to the first sampling circuit, which is operable to couple the second spin circuit with the first spin circuit by sampling the first spin circuit at one or more transitions of the second spin circuit. In embodiments, the first and second reconfigurable coupling blocks further include switches and/or other routing hardware used to selectively connect and disconnect the coupling hardware with one or more spin circuits. In embodiments, the first and second reconfigurable coupling blocks include a pin.

Examples of hardware capable of serving as a coupling unit includes passive resistors, op-amps and other active implementations of resistors, capacitors, inductors, and multiplicative couplers, to name a few.

In embodiments, the reconfigurable coupling blocks are configurable using programmable state bits storing encoding configurations of the reconfigurable coupling blocks. For example, in embodiments, the coupling switch is configured to obtain a respective switch configuration stored in memory operatively connected to the coupling switch and the variable coupling unit is configured to obtain a respective coupling configuration stored in memory operably connected to the variable coupling unit.

In embodiments, the programmable state bits are stored in memory (e.g., registers, static random access memory, dynamic random access memory, memristors, resistive random access memory, or flash memory, to name a few examples). In embodiments, memory may be localized or de-localized. For example, in embodiments, each reconfigurable coupling block include memory. As another example, in embodiments, memory be may be shared between reconfigurable coupling blocks. In other words, memory may or may not be physically present in a given Ising logic block.

In embodiments, each Ising logic block represents a single hardware implementation of a spin 318. In embodiments, a direct connection to the analog voltage in the spin, signal 308-0, is a primary bidirectional pin for each Ising logic block. In embodiments, an oscillator is used for an Oscillator Ising Machine-based FPIM.

In embodiments, the programmably reconfigurable Ising machine further includes a reconfigurable routing network configured to selectively operatively connect the first spin circuit to at least the second spin circuit based on computer instructions. In embodiments, a first spin generator of the first spin circuit and a second spin generator of the second spin circuit are interdependent when the first spin generator and the second spin generator are operatively connected, and independent when the first spin generator and the second spin generator are not operatively connected. By independent, it is meant that the first spin generator and the second spin generator are coupled with one another such that each directly affects the other. So, for example, a first spin generator that is coupled to a second spin generator, which in turn is coupled to a third spin generator, will be understood, for purposes of this application, to be interdependent with the second spin generator but independent with respect to the third spin generator.

In embodiments, for example, where a spin (e.g., spin 318) has high connectivity to other spins, mirror spins (not shown) are used. For example, the mirror spins may be forced to match each other (e.g., by connecting them via minimal resistance, to name one method, for example via signal 308-0) thereby permitting the decomposition of the small number of spins that have large connectivity for embedding into the field programmable Ising machine architecture.

Embodiments of the present disclosure represent a departure from conventional Field Programmable Gate Array architectures. In embodiments, a slightly higher connectivity may be used as compared to traditional FPGAs, resulting in an increasing the number of routing tracks. In embodiments, connectivity requirements for coupling resistors may bidirectional, and embodiments may use a form of pass-transistor based configuration rather than the direct drive architectures seen in modern FPGAs. In embodiments, much larger pass transistors may be used to ensure that coupling resistance values are primarily determined by programmable resistors rather than the interconnect. In embodiments, a different choice of logic block I/O connectivity may be selected for the local island in the island-style architecture. In embodiments, other architectural styles may be used.

In a conventional FPGA architecture, the programmable routing fabric dominates the area, delay, and energy of the FPGA. In embodiments of the present disclosure, while the area overhead of routing may be slightly lower than a traditional FPGA for field programmable Ising machines, the energy and delay metrics for field programmable Ising machines are different. In particular, in embodiments, the goal of the programmable routing may be to resistively couple slow, time-varying, analog voltages to each other, rather than transmitting a digital signal transition, as is the case in an FPGA. Accordingly, in embodiments, the programmable resistors that are part of the logic block may be designed to have higher resistance values (20′ or more) than the pass transistor logic for the interconnect, permitting us to treat the interconnect resistance as negligible. Hence, the performance and power consumption of the entire system will be dominated by the non-linear dynamics of the spin-coupled analog Ising hardware, a field programmable Ising machine will be logic-block dominated, unlike FPGAs that are interconnect dominated.

### III. FPIM Sample Metrics Using SAT Benchmarks

Two sets of SAT problems, uf20 and uf50 from DIMACS SATLIB [19](each consisting of 1000 problems), were mapped into Ising form using the techniques described in the present disclosure, uf20 problems each have 20 variables and 91 clauses, while uf50 problems feature 50 variables and 218 clauses. Employing yosys/ABC (virtual logic synthesis tools), each problem was synthesized using three different technology libraries: 1) the 2inp set of logic gates shown in Table 1, 2) NAND gates only, and 3) OR and NOT gates only. Being logically complete, NAND and OR-NOT are capable of synthesizing any SAT problem. Note that all the Ising equivalent weights for gates in the 2inp library are between −2 and +2, which is advantageous for reducing the bits of coupling resolution of our Ising formulation of SAT.

The Ising equivalent network was generated from the SATLIB problems (in .cnf format) via automated custom tools which were configured to perform gate-level synthesis using yosys and ABC, calculate Ising equivalents for the gates needed (e.g., like those in Table 1) and use them to translate the gate-level netlist into an Ising-equivalent one.

To assess hardware requirements for field programmable Ising machines, the characteristics of the Ising formulation of SAT problems that directly impact hardware resource requirements for a programmable architecture were examined. In particular, the distributions of the number of spins needed, the sparsity of connections (degree of each spin node), and the bits of coupling resolution needed to program each weight value were looked at. The distributions over the 1000 problems in each set are shown in Tables 2 to 4. Each table shows distributions for the three technology mappings used:

TABLE 2
Problem counts against the number of Ising-
mapped spins for problem sets uf20, uf50.

| | lib-* | | | | | |
|---|---|---|---|---|---|---|
| | 2inp | NAND | N/OR | 2inp | NAND | N/OR |
| # spins | uf20 | | | uf50 | | |
| 0-150 | 1 (0) | | | | | |
| 151-200 | 760 (346) | | | | | |
| 201-250 | 239 (654) | 61 | | | | |
| 251-300 | 0 (29) | 845 | 76 | | | |
| 301-350 | | 94 | 862 | | | |
| 351-400 | | | 62 | | | |
| 500-600 | | | | 922 (557) | | |
| 601-701 | | | | 78 (443) | | |
| 701-801 | | | | | 27 | |
| 801-901 | | | | | 783 | 411 |
| 901-1000 | | | | | 190 | 589 |

TABLE 3
Average number of nodes per problem against
the node degree for problem sets uf20, uf50.

| | lib-* | | | | | |
|---|---|---|---|---|---|---|
| | 2inp | NAND | NOT/OR | 2inp | NAND | NOT/OR |
| degree | uf20 | | | uf50 | | |
| 1-5 | 160.1 | 225.9 | 225.9 | 501.4 | 749.6 | 783.7 |
| 6-10 | 12.6 | 36.4 | 36.7 | 22.3 | 60.6 | 60.8 |
| 11-20 | 16.3 | 14.1 | 14.2 | 23.3 | 58.4 | 58.5 |
| 21-31 | 2.5 | 0.01 | 0.013 | 25.3 | 3.489 | 1.124 |
| 32-41 | | | | 0.817 | | |

TABLE 4
Average number of weights per problem against
the BCR needed for problem sets uf20, uf50.

| | lib-* | | | | | |
|---|---|---|---|---|---|---|
| | 2inp | NAND | NOT/OR | 2inp | NAND | NOT/OR |
| BCR | uf20 | | | uf50 | | |
| 1 | 223.4 | 319.3 | 476.4 | 745.3 | 1056 | 1375.0 |
| 2 | 357.0 | 409.0 | 457.9 | 1070.5 | 1300.6 | 1326.9 |
| 3 | 110.6 | 133.0 | 20.0 | 287.01 | 318.3 | 32.645 |
| 4 | 0.798 | 14.2 | 14.1 | 4.301 | 56.015 | 56.074 |
| 5 | 0.001 | 0.085 | 0.087 | 0.06 | 3.489 | 3.535 |

It can be seen in Table 2 that, with respect to the problems in the uf20 benchmark set, the majority (more than 900) require between 151 and 200 spins if the 2inp technology library, discussed with respect to Table 1, is applied. The numbers in parenthesis are for a modified mapping using replica (also referred to herein as “mirror”) spins. However, if the NAND-only and OR-NOT-only libraries are used, the majority range shifts to 251-300 and 301-350, respectively. The sparsity's (average number of nodes each node is connected) over all the uf20 problems are shown in Table 3. The table reveals that all three technology mappings have roughly the same sparsity characteristics, with the majority of nodes having between 1 and 5 connections. The bits of coupling resolution distribution, the count of connections that need a given number of bits to program their weight values, is shown in Table 4. It can be seen that 3 bits of coupling resolution suffice for the majority of connections over all the problems, with a smaller number of 4 and 5 bit connections also needed; and that these requirements are largely independent of the technology mapping used. This constitutes important information for planning and designing an FPIM for uf20 problems.

Similar data on the 1000 uf50 problems is shown in the later columns of Tables 2 to 4. Since these have more Boolean variables than uf20, a larger numbers of spins are required in their Ising mappings. Like for uf20, the 2inp library results in more compact mappings from a number-of-spins perspective, with every problem mapped using between 601 and 800 spins. Experiments show that the number of Ising spins grows as O(n^{1.1}) with respect to the number of SAT variables n. Note, however, that the sparsity (Table 3) and bits of coupling resolution (Table 4) distributions are very similar to those of uf20. Accordingly, as the example demonstrates, while the number of spins increases as SAT problem sizes increase, the number of connections each spin requires, as well as the number of bits required to program those connections, remains roughly the same. Thus, an advantage of scalable field programmable Ising machine architectures is that arbitrary SAT-to-Ising problem sizes are possible without having to scale up connectivity and bits of coupling resolution requirements with problem size.

To determine the interconnect complexity required for an FPIM, the open-source VPR FPGA place-and-route software package [24] was used. An FPGA architecture description file for VPR that treats each spin as a place-able component was created. Connectivity is determined by the Ising problem generated via our SAT-to-Ising automated mapping flow. The interconnect was half-populated connection blocks, with a standard Wilton-style switch block, with direct connections to resistors connected to spins. The routing tracks were all singles (single-hop per switch point). The uf20 and uf50 problems were run through place-and-route to determine the number of routing tracks necessary to support each problem.

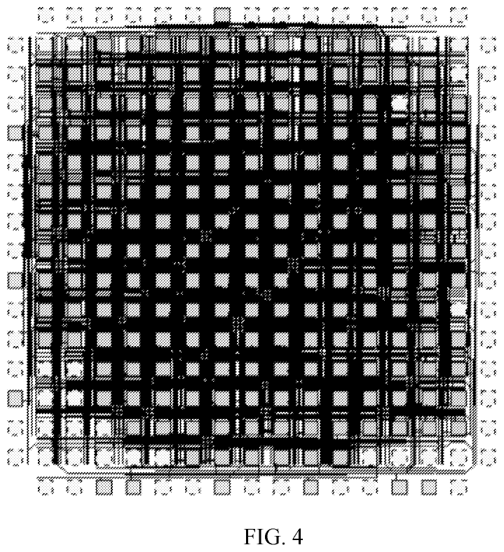

FIG. 4 shows an example SAT problem placed and routed on an FPIM in accordance with embodiments of the present invention. In particular, FIG. 4 shows a uf20 problem placed and routed on an FPIM. As depicted in FIG. 4, all the uf20 benchmarks can be mapped to an FPIM with less than 20 routing tracks in accordance with the present disclosure. While not shown, all the uf50 benchmarks can be mapped to an FPIM with less than 36 routing tracks in accordance with the present disclosure. These are within the capabilities of a modern CMOS process.

To reduce the interconnect requirements at the cost of slightly increased spins, in examples, a spin mirror step was used after the Ising problems were created. The spin mirror step examines spins that have high connectivity (more than 8), and introduces a replica spin to reduce the connectivity in the Ising formulation where the replica is generated by inserting a buffer gate prior to Ising mapping. The numbers in parentheses in Table 2 show the increase in spins as a result of this transformation. This is similar to the process of buffer insertion in digital logic to reduce delay, and here it was used to reduce the complexity of the programmable interconnect. VPR was re-ran on the 6,000 benchmarks (e.g., the 2,000 uf20 and uf50 problems, with 3 libraries per problem) using this step.

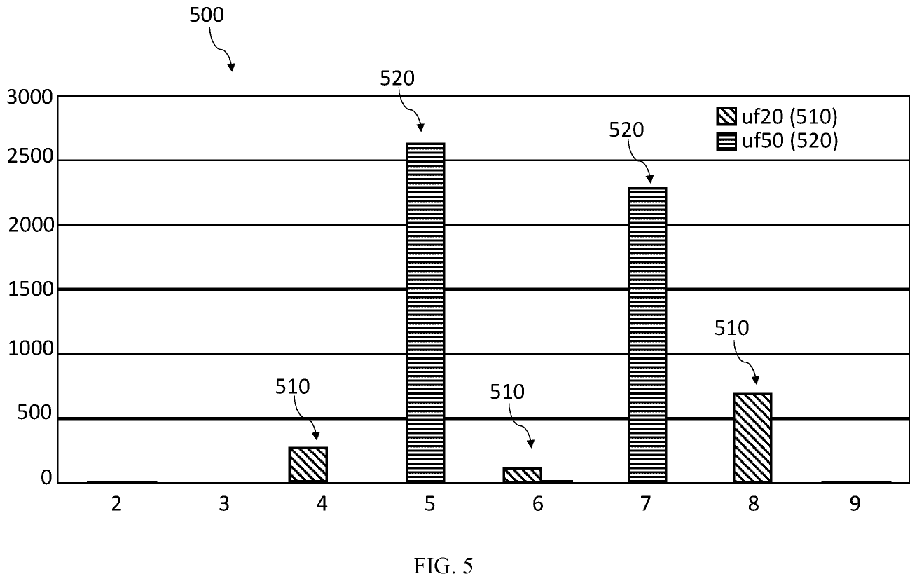

FIG. 5 is a histogram (500) of routing track requirements for an example where mirrored spins are used in accordance with embodiments of the present invention. The histogram is across all libraries and benchmarks (3,000 scenarios for uf20 and for uf50). As shown in histogram 500 of FIG. 5, all the uf20 (510) benchmarks were routable with 6 tracks for a 6.3% increase in number of spins, and all the uf50 (520) benchmarks were routable with 9 tracks for a 3.9% increase in number spins. At the same time, implementation of the spin mirror step resulted in a 3.3 times to 4 times reduction in the number of routing tracks.

Using the above information, the areas of all the components needed to make an FPIM, including analog spin circuits, programmable resistors implemented using transmission gate ladders, and transmission gate based switch boxes, connection boxes and input MUXes was estimated. The overall estimate came to about 10 Mλ² per spin, where λ represents half of the technology's feature size. Unlike in FPGAs, this area is strongly dominated by the analog components, the analog spins and programmable coupling resistors. In a 65 nm process, for example, a 1000-spin field programmable Ising machine, which is more than adequate for all the uf50 and uf20 problems, would occupy about 10 mm², demonstrating that field programmable Ising machines are in fact a practical way to implement configurable Ising Machine solvers.

Now that embodiments of the present invention have been shown and described in detail, various modifications and improvements thereon can become readily apparent to those skilled in the art. Accordingly, the exemplary embodiments of the present invention, as set forth above, are intended to be illustrative, not limiting. The spirit and scope of the present invention is to be construed broadly.

### REFERENCES

1 M. W. Johnson et al., “Quantum annealing with manufactured spins,” Nature, vol. 473, no. 7346, pp. 194-198, 2011.
2 Z. Wang et al., “Coherent Ising machine based on degenerate optical parametric oscillators.” Phvs. Rev. A. vol. 88, no. 6, 2013.
3 T. Wang, L. Wu, P. Nobel, and J. Roychowdhury, “Solving combina torial optimisation problems using oscillator based Ising machines,” Natural Computing, pp. 1-20, April 2021.
4 R. Afoakwa et al., “BRIM: Bistable Resistively-Coupled Ising Machine,” in IEEE HPCA, 2021, pp. 749-760.
5 J. Roychowdhury, “Bistable Latch Ising Machines,” Proc. UCNC, October 2021.
6 I. Ahmed et al., “A Probabilistic Compute Fabric Based on Coupled Ring Oscillators for Solving Combinatorial Optimization Problems,” IEEE J. Solid-State Ckts., vol. 56, no. 9, September 2021.
7 K. Tatsumura, M. Yamasaki, and H. Goto, “Scaling out Ising machines using a multi-chip architecture for simulated bifurcation,” Nature Electronics, vol. 4, no. 3, pp. 208-217, 2021.
8 K. Tatsumura, A. R. Dixon. and H. Goto. “FPGA-based simulated bifurcation machine,” in Proc. FPL, 2019, pp. 59-66.
9 A. Lucas, “Ising formulations of many NP problems,” Frontiers in Physics, vol. 2, p. 5, 2014.
10 M. Kim et al., “Leveraging quantum annealing for large MIMO processing in centralized radio access networks.” in Proc. ACM SIG on Data Comm., 2019.
11 J. Roychowdhury, J. Wabnig and K. P. Srinath, “Performance of Oscillator Ising Machines on Realistic MU-MIMO Decoding Problems.”
12 N. Sagan and J. Roychowdhury, “DaS: Implementing Dense Ising Machines Using Sparse Resistive Networks,” in Proc. ICCAD, November 2022.
13 K. Boothby et al., “Next-Generation Topology of D-Wave Quantum Processors,” arXiv:2003.00133, 2020.
14 J. Su. T. Tu. and L. He, “A quantum annealing approach for Boolean Satisfiability problem,” in Proc. IEEE DAC, 2016.
15 Y. Sugie et al., “Minor-embedding heuristics for large-scale annealing processors with sparse hardware graphs of up to 102,400 nodes,” Soft Comput., vol. 25, no. 3, 2021.
16 T. Wang. L. Wu and J. Rovchowdhury, “New Computational Results and Hardware Prototypes for Oscillator-based Ising Machines,” in Proc. IEEE DAC, 2019, pp. 239:1-239:2.
17 C. Wolf, J. Glaser, and J. Kepler, “Yosys-a free Verilog synthesis suite,” in Proc. Austrochip, 2013.
18 R. K. Bravton and A. Mishchenko, “ABC: An Academic Industrial-Strength Verification Tool,” in Proc. CAV, 2010.
19 H. H. Hoos and T. Stu~tzle, “SATLIB: An online resource for research on SAT,” SAT, vol. 2000, pp. 283-292, 2000.
20 R. M. Karp, “Reducibility among combinatorial problems,” in Complexity of Computer Computations. Springer. 1972. pp. 85-103.
21 L. Zhang and S. Malik, “The Quest for Efficient Boolean Satisfiability Solvers,” in International Conference on Computer Aided Verification, 2002, pp. 17-36.
22 J. Marques-Silva, “Practical applications of Boolean Satisfiability,” in 9th Int. Workshop on Discrete Event Syst., 2008.
23 J. Teifel and R. Manohar, “Highly pipelined asynchronous FPGAs,” in Proc. FPGA, 2004, pp. 133-142.
24 V. Betz and J. Rose, “VPR: A new packing, placement and routing tool for FPGA research,” in Proc. FPL. 1997, pp. 213-222.

What is claimed is:

1. A programmably reconfigurable Ising machine comprising:
a) a plurality of spin circuits, including a first spin circuit and a second spin circuit, wherein each of the plurality of spin circuits comprises:
i) a spin generator;
ii) a set of reconfigurable coupling blocks operatively connected to the spin generator, wherein each of the reconfigurable coupling blocks comprises:
1) a coupling switch operatively connected to the spin generator;
2) a variable coupling unit operatively connected to the coupling switch; and
3) a pin operatively connected to the variable coupling unit;
b) a reconfigurable routing network configured to selectively operatively connect the first spin circuit to at least the second spin circuit based on computer instructions, wherein a first spin generator of the first spin circuit and a second spin generator of the second spin circuit are interdependent when the first spin generator and the second spin generator are operatively connected and independent when the first spin generator and the second spin generator are not operatively connected.

2. The programmably reconfigurable Ising machine of claim 1, wherein the spin generator includes an oscillator.

3. The programmably reconfigurable Ising machine of claim 1, wherein the spin generator includes a latch.

4. The programmably reconfigurable Ising machine of claim 1, wherein at least one of the plurality of spin circuits comprises at least two spin generators.

5. The programmably reconfigurable Ising machine of claim 1, wherein the programmably reconfigurable Ising machine includes memory operatively connected to the coupling switch and the variable coupling unit, wherein the coupling switch is configured to obtain a respective switch configuration stored in the memory, and wherein of the variable coupling unit is configured to obtain a respective coupling configuration stored in the memory.

6. The programmably reconfigurable Ising machine of claim 5, wherein the memory is static random access memory.

7. The programmably reconfigurable Ising machine of claim 5, wherein the memory is flash memory.

8. The programmably reconfigurable Ising machine of claim 1, wherein at least one of the plurality of spin circuits further comprises iii) a wire operatively connected to the spin generator and a pin and configured to carry an analog signal.

9. The programmably reconfigurable Ising machine of claim 8, wherein the analog signal is configured to set a spin of a spin generator of at least one of the plurality of spin circuits to a predetermined value.

10. The programmably reconfigurable Ising machine of claim 8, wherein the analog signal is configured to set a first spin of the first spin circuit to a value of a second spin of the second spin circuit.

11. A programmable reconfigurable Ising machine comprising:
a) A plurality of spin circuits, including a first spin circuit and a second spin circuit, wherein each of the plurality of spin circuits comprises:
i) a spin generator; and
ii) a set of reconfigurable coupling blocks operatively connected to the spin generator; and
b) a reconfigurable routing network configured to selectively operatively connect the first spin circuit to at least the second spin circuit based on computer instructions, wherein a first spin generator of the first spin circuit and a second spin generator of the second spin circuit are interdependent when the first spin generator and the second spin generator are operatively connected and independent when the first spin generator and the second spin generator are not operatively connected.

12. The programmably reconfigurable Ising machine of claim 1, wherein the first spin circuit and the second spin circuit are connected via at least one connection block.

13. The programmably reconfigurable Ising machine of claim 1, wherein the first spin circuit and the second spin circuit are connected via at least two connection blocks and a switch block.

14. The programmably reconfigurable Ising machine of claim 1, wherein the plurality of spin circuits includes a third spin circuit.

15. The programmably reconfigurable Ising machine of claim 14, wherein the reconfigurable routing network is further configured to selectively operatively connect the third spin circuit to the first spin circuit, the third spin circuit to the second spin circuit, and the third spin circuit to the first and second spin circuit.

16. The programmably reconfigurable Ising machine of claim 1, wherein the plurality of spin circuits includes at least 250 spin circuits.

17. The programmably reconfigurable Ising machine of claim 1, wherein the plurality of spin circuits includes at least 500 spin circuits.

18. The programmably reconfigurable Ising machine of claim 1, wherein the plurality of spin circuits includes at least 1,000 spin circuits.

19. The programmably reconfigurable Ising machine of claim 1, wherein the plurality of spin circuits includes at least 2,000 spin circuits.

20. The programmably reconfigurable Ising machine of claim 1, wherein the plurality of spin circuits includes at least 10,000 spin circuits.
